(19) United States
(12) Patent Application Publication
(10) Pub. No.: US 2011/0140685 A1
(43) Pub. Date: Jun. 16, 2011

(54) METHOD FOR DIAGNOSING A LOAD DROP

(76) Inventors: Yanqi Zu, Vaihingen (DE); Stefan Schempp, Wernau (DE); Matthias Bitzer, Gaertringen (DE)

(21) Appl. No.: 12/736,848

(22) PCT Filed: Apr. 22, 2009
(86) PCT No.: PCT/EP2009/054791

§ 371 Date: Feb. 9, 2011

(30) Foreign Application Priority Data
May 26, 2008 (DE) 10 2008 001 971.2

(51) Int. Cl. G01R 19/00; G06F 19/00

(52) U.S. Cl. 324/76.11; 702/64

(57) ABSTRACT

A method for diagnosing a load drop in a piezo actuator in an injection device, a voltage being measured and being compared to a threshold voltage (24) for the diagnosis, the load drop being present if the measured voltage is greater than the threshold voltage (24). The present invention also relates to a device for diagnosing a load drop in a piezo actuator in an injection device, to a computer program and to a computer program product.

### BACKGROUND OF THE INVENTION

1. Field of the Invention

The present invention relates to a method and a device for diagnosing a load drop for a piezo actuator for an injection device, as well as a computer program and a computer program product.

2. Description of Related Art

An injection device or an injection system, which is also designated as a common rail system, for internal combustion engines is developed to introduce fuel into a combustion chamber of an internal combustion engine. For this purpose, the injection device may have a piezo actuator, for instance a common rail piezo actuator, for acting upon an injection valve. A load drop that is created by an interruption in a line of a cable harness, for example, in the injection device having the piezo actuator, leads to the piezo actuator not being charged, and therefore the injections being omitted. In control unit generation EDC17 of Robert Bosch GmbH, a diagnosis of the load drop via output stage component CY372 is provided, however, this diagnosis functions only in certain control unit configurations.

Published European document patent application document EP 1 138 905 B1 describes a method for detecting a load decrease during the activation of piezoelectric elements, in order to detect a load drop in the electrical load of one or more of the piezoelectric elements, in a reliable manner. In this context, a load drop of a piezoelectric element is detected by monitoring whether a desired voltage is reached at the piezoelectric element in less than a predetermined minimum time. If such a voltage is reached in less than the minimum time, a signal is produced, to indicate that a load drop has occurred for this piezoelectric element. The use of such a signal enables one to introduce countermeasures which may be necessary to rectify faults. The rectification of faults may be carried out in a workshop, for example. The signal may also be used for storing a fault message in an electronic memory.

### SUMMARY OF THE INVENTION

The present invention relates to a method for diagnosing a load drop at a piezo actuator in an injection device or an injection system in an internal combustion engine. To carry out the diagnosis, a voltage that is present at the piezo actuator is measured, and compared to a threshold voltage. The load drop that is to be diagnosed is present if the measured voltage is greater than the threshold voltage.

The method is suitable for injection devices that are developed as so-called common rail injection devices, for example. Such injection devices also have piezo actuators, which are appropriately developed as CR piezo actuators. The piezo actuators are provided for acting upon, and in the process, for operating a valve module of an injection valve of the injection device, so as to implement an injection process, so that thereby the injection valve is opened and fuel is filled into a combustion chamber of the internal combustion engine. In common rail injection devices it is provided that pressure generation and injection of fuels are decoupled with respect to time and location. In this context, the injection pressure is produced by a separate high-pressure pump, which does not necessarily have to be driven synchronously to the injection processes.

Within the scope of the method, as a function of an operating point of the injection device, the threshold voltage provided for the comparison may be provided automatically and/or dynamically. In this instance, the threshold voltage is formed from a sum of a setpoint voltage Uₛₑₜₚₒᵢₙₜ in addition to an offset voltage ΔU. Setpoint voltage Uₛₑₜₚₒᵢₙₜ, as a first addend for the threshold voltage, is typically a function of an operating parameter of the injection device, such as of the pressure of the transportation fuel or combustion fuel in the injection device. For the implementation of the method, this pressure is therefore determined, and thus monitored, by a control unit, so that it is possible to adjust setpoint voltage Uₛₑₜₚₒᵢₙₜ so as to be operational, and consequently to provide the execution of one embodiment of the method. Offset voltage ΔU as the second addend for the threshold voltage may also be selected with reference to the application and/or operationally. A value for offset voltage ΔU may also be provided operationally for this by the control unit, based on operating parameters. According to this, the threshold voltage is a function of at least one operating parameter of the injection device, such as the pressure of the transportation fuel.

The voltage, that is to be measured within the scope of the method, is measured, at the earliest, as of the end of a charging process for charging the piezo actuator during an injection process. The measurement of this voltage usually takes place after the charging process, typically immediately after the end of the charging process.

The load drop of the piezo actuator, that is to be diagnosed in one variant of the method, may have different causes. By making the diagnosis of the load drop it is possible, for example, to prove an interruption in a cable harness, via which the piezo actuator is supplied with energy, starting from the control unit, on the inside of the injection device. Consequently, it is possible to prove that there is an interruption within at least one line, by which the piezo actuator is connected to the control unit, that is usually longer than in the case of a so-called loose connection. However, the method may also be used to prove that there are load drops that have other causes.

The present invention also relates to a device for diagnosing a load drop in a piezo actuator in an injection device. This device is developed to measure a voltage and furthermore to compare this measured voltage to a threshold voltage. Using the device, one may diagnose the presence of a load drop if the measured voltage is greater than the threshold voltage.

In the embodiment, this device may have a control unit or an engine control unit for an injection device. It may also be provided that the device have a bank voltage measuring bridge that is developed to measure the voltage. In this regard, it may be provided that the bank voltage measuring bridge be developed as a component of the control unit. The device, typically the control unit as a component of the device, is developed to collaborate with the injection device, and in the process, to check on, and thus to control and/or regulate injection processes that are to be carried out by the injection device, independent of whether there is a load drop or not.

In the embodiment, using this invention, a diagnosis is possible that is independent of certain configurations of the control unit hardware. Furthermore, the diagnosis provided within the scope of the present invention, takes place using relative thresholds to a setpoint value, and not, as was the case in procedures up to now, using absolute values, which are typically fixed ahead of time.

Using this design, the detection probability of a fault in a load drop may be clearly increased and, at the same time, the robustness with respect to false diagnoses may be increased. In addition, the new diagnosis function may be set with respect to use or applicatively, whereas up to now, procedural methods have offered no possibility of such an adaptation.

Using the present invention, it is also possible, among other things, to implement a diagnostic load drop also for configurations of control units that have high parasitic capacities.

The system described is designed to execute all of the steps of the method introduced. Individual steps of this method are also able to be carried out by individual components of the system. Furthermore, functions of the system, or functions of individual components of the system, may be implemented as steps of the method.

In addition, the invention relates to a computer program having program code means for carrying out all of the steps of a described method, when the computer program is executed on a computer or a corresponding central processing unit, in particular in a system according to the present invention.

The computer program product according to the present invention, having program code means, which are stored on a computer-readable data carrier, is designed to execute all of the steps of a described method when the computer program is executed on a computer or a corresponding processing unit, in particular a system according to the present invention.

In the function for the diagnosis of the load drop, it is assumed that no detection takes place via the application specific integrated circuit, ASIC, and as a result of this, no emergency discharge takes place either. Within the scope of the present invention, it may either be provided that the detection is, or will be deactivated by the ASIC, or that this is not functioning.

In the execution of the method, such a detection of the load drop by the ASIC is not required. When there is a load drop, the voltage increases further as a result of the time-controlled charging process and the greatly lowered capacitance. At the bank voltage measuring bridge of the control unit, the voltage curve that is to be checked sets in. In the case of a load drop, since the capacitance to be charged is reduced to the parasitic capacitance of the output stage, there comes about a substantially steeper voltage gradient than in a fault-free system. In the CY372 output stage, the charging takes place up to the achievement of a constant charging time, typically within 100 μs.

When the method is applied, since the load drop is able to be diagnosed and thus detected by the control unit, it is possible that, starting from the control unit, measures may be taken for rectifying the load drop.

In the fault case, that is, when there is a load drop, the voltage increases to a maximum value of the buffer voltage U_{buffer} and remains at this level until the output stage ends the charging process at a second point in time. After that, the voltage drops again. At a point in time directly after the ending of the charging process, or as of the ending of the charging process, a voltage measurement is now performed in the embodiment of the method. A voltage measured value ascertained in this context, or rather a measured value for the voltage, is compared to the threshold voltage which is greater than setpoint voltage Uₛₑₜₚₒᵢₙₜ by voltage offset U. If the voltage measured value is greater than voltage threshold Uₛₑₜₚₒᵢₙₜ+U, the load drop is detected. Since the setpoint voltage is typically a function of the rail pressure, the threshold is automatically displaced matched to an operating point of the injection device. In the case of high rail pressures, and accordingly in the case of high pressures of the fuels in the injection device and high setpoint voltages connected therewith, this may also lead to the threshold voltage being higher than buffer voltage U_{buffer}, and in these cases, an automatic deactivation of the diagnosis takes place, which clearly increases the robustness compared to a false diagnosis.

In one implementation of the present invention, in the case of a measurement of the voltage curve in response to a load drop in the control unit, and in the case of a corresponding diagnostic reaction, the function provided within the scope of the present invention is implemented.

Further advantages and refinements of the present invention are derived from the description and the accompanying drawings.

It is understood that the features mentioned above and the features yet to be described below may be used not only in the combination given in each case but also in other combinations or individually, without departing from the scope of the present invention.

### BRIEF DESCRIPTION OF THE DRAWINGS

FIG. 1 shows a first diagram on voltage curves in a schematic representation.

FIG. 2 shows a second diagram on voltage curves in a schematic representation.

FIG. 3 shows a specific embodiment of a system according to the present invention in a schematic representation.

### DETAILED DESCRIPTION OF THE INVENTION

The present invention is represented schematically in the drawings with the aid of specific embodiments, and is described in detail below with reference to the drawings.

The figures are described in a cohesive and comprehensive manner; the same reference numerals denote identical components.

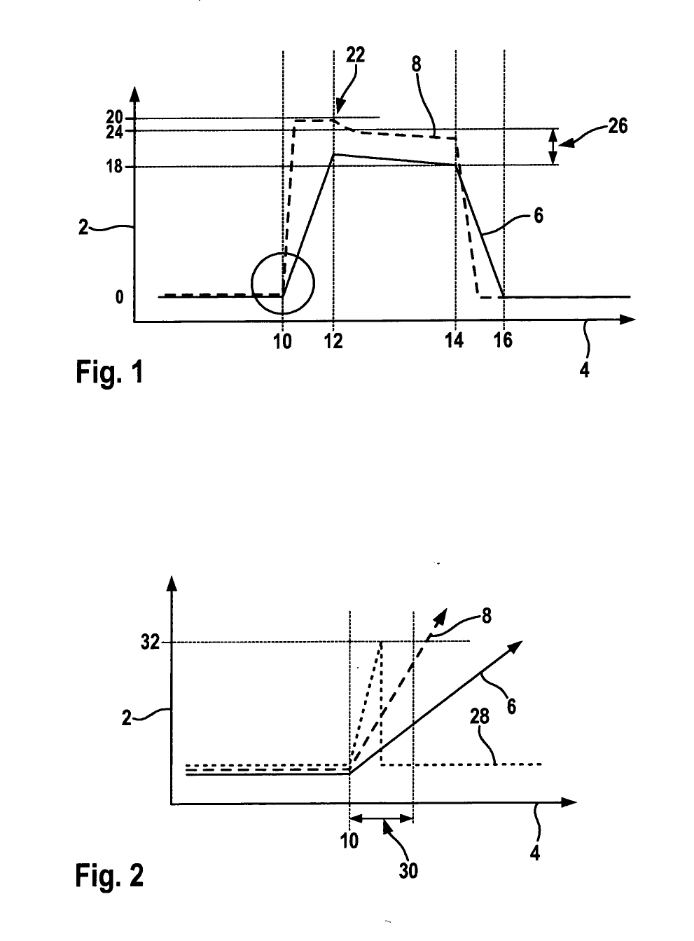

The diagram shown in FIG. 1 includes a vertically oriented axis 2 for a voltage, which is plotted against a horizontally oriented axis 4 for the time. Within this diagram, a first voltage curve 6 (solid line) and a second voltage curve 8 (dashed line) are shown. Along horizontally oriented axis 4 for the time, a first time 10, a second time 12, a third time 14 and a fourth time 16 are indicated. A value for a setpoint voltage 18 Uₛₑₜₚₒᵢₙₜ and a value for a buffer voltage 20 U_{buffer} are given along vertically oriented axis 2 for the voltage.

In the diagram, a first voltage curve 6 shows a typical charging curve in a faultless injection device. The charging process for a piezo actuator of the injection device begins at a first time 10. This charging process lasts up to second time 12. The voltage drops gently thereafter up to a third time 14, at which the discharge process begins. In this time, in the regulated state, setpoint voltage 18 Uₛₑₜₚₒᵢₙₜ should be reached. At a fourth time 16, in reaching a voltage of 0 V, the discharging process is finished.

Second voltage curve 8 in the diagram in FIG. 1 comes about when a load drop occurs at the piezo actuator, which is caused by an interruption of the supply of electrical energy to the piezo actuator. One may see, in this case, that the voltage rises more steeply than in the faultless case, and also reaches a much higher value than in the faultless case.

Since the presence of a load drop is not predictable, a voltage measurement 22 is carried out after second time 12 and at a fifth time, when carrying out an embodiment of the method according to the present invention. A value measured at this fifth time is compared to the value for a threshold voltage 24. The value for threshold voltage 24 is given by the sum of setpoint voltage 18 Uₛₑₜₚₒᵢₙₜ and an offset voltage 26 ΔU. It is provided among other things that setpoint voltage 18 Uₛₑₜₚₒᵢₙₜ is a function of the pressure of a fuel within the injection device. Accordingly, the value for threshold voltage 24 is also a function of this pressure. In he embodiment of the method, threshold voltage 24 is therefore adapted to a running operation of the injection device.

One condition that speaks for the presence of the load drop on the piezo actuator, is that the voltage measured at the fifth time is greater than threshold voltage 24. If the voltage measured at the fifth time is lower than threshold voltage 24, a load drop is not diagnosed within the scope of the method. Second voltage curve 8, shown in the diagram of FIG. 1, that occurs in the defective case, is measured on a bank voltage measuring bridge in the control unit.

The diagram of FIG. 2 shows a detail of the diagram of FIG. 1 that is circled in the diagram of FIG. 1, in which a third voltage curve 28 (dotted line) is additionally shown. This third voltage curve 28 is measured by an application specific integrated circuit (ASIC) of the control unit, when there is a load drop.

Therefore, the diagram of FIG. 2 shows the detection mechanism by the ASIC in the case of the load drop, by third voltage curve 28 (dotted line). Because of the interruption, since the piezo actuator is no longer connected, only the parasitic capacitances of the output stage of the control unit are charged. Since these are very small, the voltage rises greatly in response to the preset current. Within a time interval T_uTOMin 30, if a second voltage threshold uTOMin 32 is exceeded, the ASIC detects the load drop. Thereupon an immediate discharge takes place, and a corresponding message to the CPU or a main processor via an SPI or serial peripheral interface. However, by using means for electromagnetic compatibility (EMC), in certain control unit configurations, the parasitic capacities may be so large that the voltage increase does not take place rapidly enough. In this case, detection by the ASIC fails.

The voltage increases up to the maximum available buffer voltage 20 U_{buffer}, and remains at this level until the charging switch is opened at second time 12. Because of the transfer inductance, the voltage then first drops a little more and then persists at a high level until the discharge process. In this case, the diagnosis of the load drop takes place using the method described by FIG. 1.

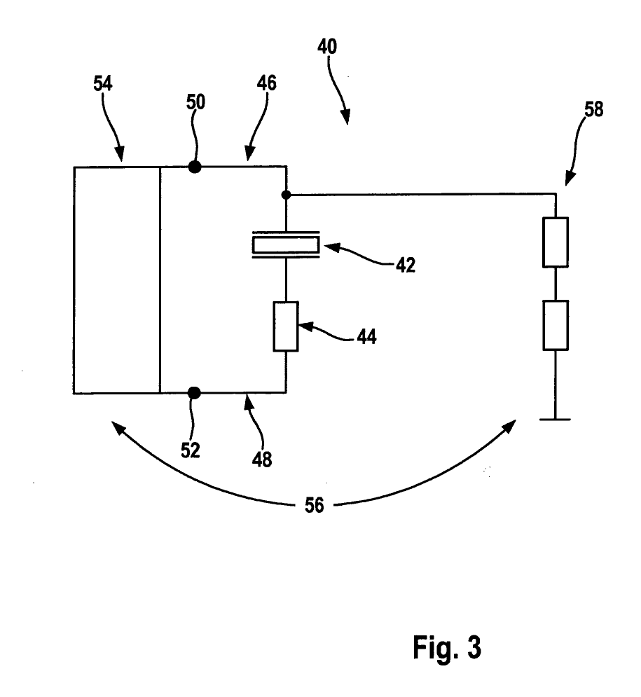

In a schematic representation, FIG. 3 shows a specific embodiment of a device 40, according to the present invention, for a so-called common rail injection device or a common rail injection system for an internal combustion engine.

This device 40 includes a piezo actuator 42, which is designed to act upon a valve needle of the injection device. This piezo actuator 42 is connected in series with a cable harness resistor 44. Piezo actuator 42 and cable harness resistor 44 are connected via two electrical lines 46, 48 to a positive pole 50 and a negative pole 52 of a first control unit component 54 of a control unit 56 as an additional component of device 40. It is provided that control unit 56 be developed to supply piezo actuator 42 with electrical energy via electrical lines 46, 48, so that, during ideal operation, there is a voltage present at piezo actuator 42 which makes it possible to act upon an injection valve for carrying out an injection process.

As an additional control unit component 58, schematically shown control unit 56 has a bank voltage measuring bridge, which is developed for measuring the voltage that is present at piezo actuator 42.

1-11. (canceled)

12. A method for diagnosing a load drop on a piezo actuator in an injection device, comprising: measuring a voltage and comparing the measured voltage to a threshold voltage, wherein a load drop is present if the measured voltage is greater than the threshold voltage.

13. The method as recited in claim 12, wherein the threshold voltage is formed from the sum of a setpoint voltage Uₛₑₜₚₒᵢₙₜ and an offset voltage ΔU.

14. The method as recited in claim 13, wherein the setpoint voltage Uₛₑₜₚₒᵢₙₜ is a function of a pressure of a fuel in the injection device.

15. The method as recited in claim 12, wherein the voltage is measured as of the end of a charging process during an injection process.

16. The method as recited in claim 13, wherein the voltage is measured as of the end of a charging process during an injection process.

17. The method as recited in claim 14, wherein the voltage is measured as of the end of a charging process during an injection process.

18. The method as recited in claim 13, wherein the offset voltage ΔU is selected with reference to the application.

19. The method as recited in claim 14, wherein the offset voltage ΔU is selected with reference to the application.

20. The method as recited in claim 15, wherein the offset voltage ΔU is selected with reference to the application.

21. The method as recited in claim 12, wherein an interruption in a cable harness of the injection device is proven by the diagnosis of the load drop.

22. The method as recited in claim 13, wherein an interruption in a cable harness of the injection device is proven by the diagnosis of the load drop.

23. The method as recited in claim 14, wherein an interruption in a cable harness of the injection device is proven by the diagnosis of the load drop.

24. A device for diagnosing a load drop on a piezo actuator in an injection device, the diagnosing device being capable of measuring a voltage and comparing the measured voltage to a threshold voltage so as to diagnose a presence of a load drop if the measured voltage is greater than the threshold voltage.

25. The device as recited in claim 24, which includes a control unit.

26. The device as recited in claim 24, which includes a bank voltage measuring bridge for measuring the voltage.

27. The device as recited in claim 25, which includes a bank voltage measuring bridge for measuring the voltage.

28. A computer program having program code means for implementing the method as recited in claim 12 when the computer program is executed on a computer or a corresponding processing unit.

29. A computer program product having program code means, which are stored on a computer-readable data carrier, for implementing the method as recited in claim 12 when the computer program is executed on a computer or a corresponding processing unit.
